(19) United States
(12) Patent Application Publication
(10) Pub. No.: US 2026/0052793 A1
(43) Pub. Date: Feb. 19, 2026

(54) CHIP PACKAGING STRUCTURE

(71) Applicant: TONG HSING ELECTRONIC INDUSTRIES, LTD., Taoyuan City (TW)

(72) Inventors: Tien-Hao Cheng, Taoyuan City (TW); Cheng-Chang Wu, Taoyuan City (TW); Li-Chun Hung, Taoyuan City (TW)

(73) Assignee: TONG HSING ELECTRONIC INDUSTRIES, LTD., Taoyuan City (TW)

(21) Appl. No.: 18/911,572

(22) Filed: Oct. 10, 2024

(30) Foreign Application Priority Data
Aug. 16, 2024 (TW) 113131010

(51) Int. Cl. H01L 27/146; H01L 23/00; H01L 23/31

(52) U.S. Cl. CPC H10F 39/811; H01L 23/3135; H01L 23/315; H01L 24/32; H01L 24/48; H01L 24/73; H01L 2224/32225; H01L 2224/48229; H01L 2224/48491; H01L 2224/73265; H10F 39/18; H10F 39/804

(57) ABSTRACT

A chip packaging structure includes a first substrate, an image sensor chip, a first molding layer, conductive pillars, metal wires, an adhesive layer, a second substrate, and a second molding layer. The first substrate includes traces between its upper surface and lower surface. The image sensor chip is fixed on the first substrate. The first molding layer is disposed on the first substrate and covers a side surface of the image sensor chip. The conductive pillars are disposed in the first molding layer, and the metal wires electrically connects the image sensor chip to the conductive pillars. The adhesive layer is disposed on the first molding layer and surrounds the image sensor chip. The second substrate is fixed on the adhesive layer. The second molding layer is disposed on the first molding layer and covers a side surface of the adhesive layer and a side surface of the second substrate.

### CROSS-REFERENCE TO RELATED APPLICATION

This non-provisional application claims priority under 35 U.S.C. § 119(a) to Patent Application No. 113131010 filed in Taiwan, R.O. C. on Aug. 16, 2024, the entire contents of which are hereby incorporated by reference.

### BACKGROUND

### Technical Field

The present disclosure relates to a chip packaging structure, and in particular to a chip packaging structure of an image sensor chip.

### Related Art

FIG. 1 shows a chip packaging structure 90 called as a mini Plastic Ball Grid Array (PBGA), and the chip packaging structure mainly includes a carrier plate 91, a CMOS image sensor chip 92, metal wires 93, a glass cover 94, an adhesive 95 and a molding adhesive 96. The CMOS image sensor chip 92 is fixed on the carrier plate 91 in a mode that an active surface faces upwards. The CMOS image sensor chip 92 is electrically connected to the carrier plate 91 by the metal wires 93 in a wire bonding mode. The glass cover 94 is arranged on the CMOS image sensor chip 92 through the adhesive 95, so that the CMOS image sensor chip 92 is sealed in a closed space 900 defined by the glass cover 94, the adhesive 95 and the carrier plate 91. Finally, side surfaces of the glass cover 94 and the adhesive 95 are packaged by the molding adhesive 96.

The packaging structure of the mini PBGA has a problem of large closed space 900, so more air will be stored in the packaging structure. Because the glass cover 94, the adhesive 95, the carrier plate 91 and the like are all non-ventilatible elements, when the packaging structure is subjected to other heat treatment processes (such as a reflow soldering process) subsequently, the air in the closed space 900 will lead to a pressure difference between an inside of the closed space 900 and the outside due to thermal expansion, and the pressure difference may cause the failure or defect of a bonding surface between the glass cover 94 and the adhesive 95, influencing the yield and reliability of the whole packaging structure.

### SUMMARY

In view of the above, the inventor of the present disclosure provides a chip packaging structure, including a first substrate, an image sensor chip, a first molding layer, multiple conductive pillars, multiple metal wires, an adhesive layer, a second substrate and a second molding layer. The first substrate includes an upper surface, a lower surface, a side surface, and traces between the upper surface and the lower surface. The upper surface of the first substrate has a die-bonding area and multiple upper contacts disposed around the die-bonding area, and the lower surface of the first substrate has multiple lower contacts. The upper contacts on the upper surface of the first substrate are electrically connected to the lower contacts on the lower surface thereof through the traces. The image sensor chip is fixed on the die-bonding area on the upper surface of the first substrate. An active surface of the image sensor chip includes an image sensing area and multiple solder pads disposed around the image sensing area. The first molding layer is disposed on the upper surface of the first substrate and covers a side surface of the image sensor chip, an outer side surface of the first molding layer is flush with the side surface of the first substrate, and an inner side surface of the first molding layer is flush with the side surface of the image sensor chip. The multiple conductive pillars are disposed in the first molding layer and respectively correspond to the multiple upper contacts of the first substrate. A bottom end of each conductive pillar is electrically connected to one of the upper contacts, and a top end of each conductive pillar is exposed on an upper surface of the first molding layer. One end of each metal wire is electrically connected to one solder pad of the image sensor chip, and the other end of each metal wire is electrically connected to the top end of one conductive pillar. The adhesive layer is disposed on the upper surface of the molding layer and surrounds the image sensor chip. The second substrate is fixed on the upper surface of the adhesive layer. The second molding layer is disposed on the upper surface of the first molding layer and covers a side surface of the adhesive layer and a side surface of the second substrate.

### BRIEF DESCRIPTION OF THE DRAWINGS

FIG. 1 is a schematic diagram of a mini PBGA packaging structure.

FIG. 2 is a schematic diagram of a chip packaging structure according to an embodiment of the present disclosure.

FIG. 3A is a schematic diagram of overlook view of a first substrate according to an embodiment of the present disclosure.

FIG. 3B is a schematic diagram of upward view of a first substrate according to an embodiment of the present disclosure.

FIG. 3C is a schematic diagram of a section of a first substrate according to an embodiment of the present disclosure.

FIG. 3D is a schematic diagram of a section of an image sensor chip fixed on a first substrate.

FIG. 3E is a schematic diagram of overlook view of an image sensor chip fixed on a first substrate.

FIG. 3F is a schematic diagram of a section of a protective layer formed on an active surface of an image sensor chip.

FIG. 3G is a schematic diagram of overlook view of a protective layer formed on an active surface of an image sensor chip.

FIG. 3H is a schematic diagram of a section of a conductive pillar formed on an upper contact on a first substrate.

FIG. 3I is a schematic diagram of a section of a first molding layer formed on a first substrate.

FIG. 3J is a schematic diagram of a section of a first molding layer thinned and exposed on a top end of a conductive pillar.

FIG. 3K is a schematic diagram of a section of wire bonding on a solder pad of an image sensor and a top end of a conductive pillar.

FIG. 3L is a schematic diagram of a section of a second substrate fixed above an image sensor.

FIG. 3M is a schematic diagram of a section of a second molding layer formed on a first molding layer.

FIG. 4 is a schematic diagram of a section of a central area and a peripheral area of a second substrate.

FIG. 5 is a flowchart of a manufacturing method of a chip packaging structure according to an embodiment of the present disclosure.

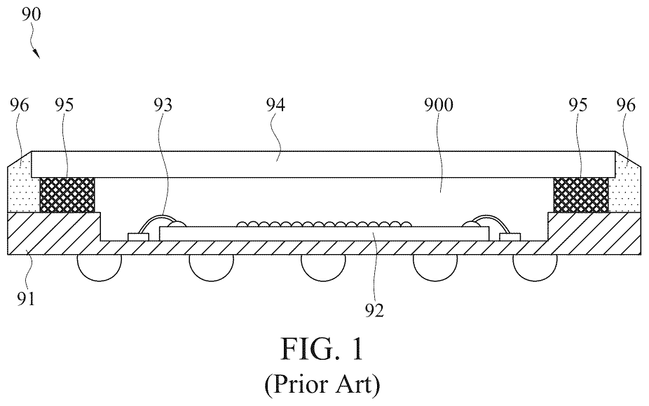

### DETAILED DESCRIPTION

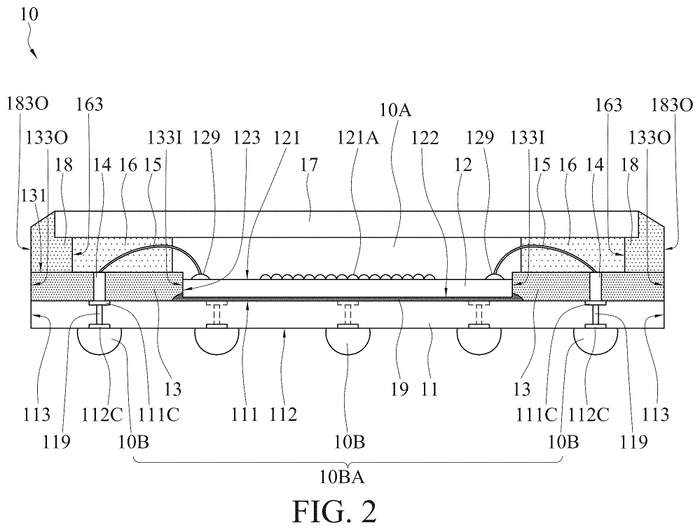

Referring to FIG. 2, which is a schematic diagram of a chip packaging structure 10 according to an embodiment of the present disclosure. The chip packaging structure 10 according to this embodiment is suitable for packaging of a CMOS image sensor chip and mainly includes a first substrate 11, an image sensor chip 12, a first molding layer 13, multiple conductive pillars 14, multiple metal wires 15, an adhesive layer 16, a second substrate 17 and a second molding layer 18, which are detailed as follows.

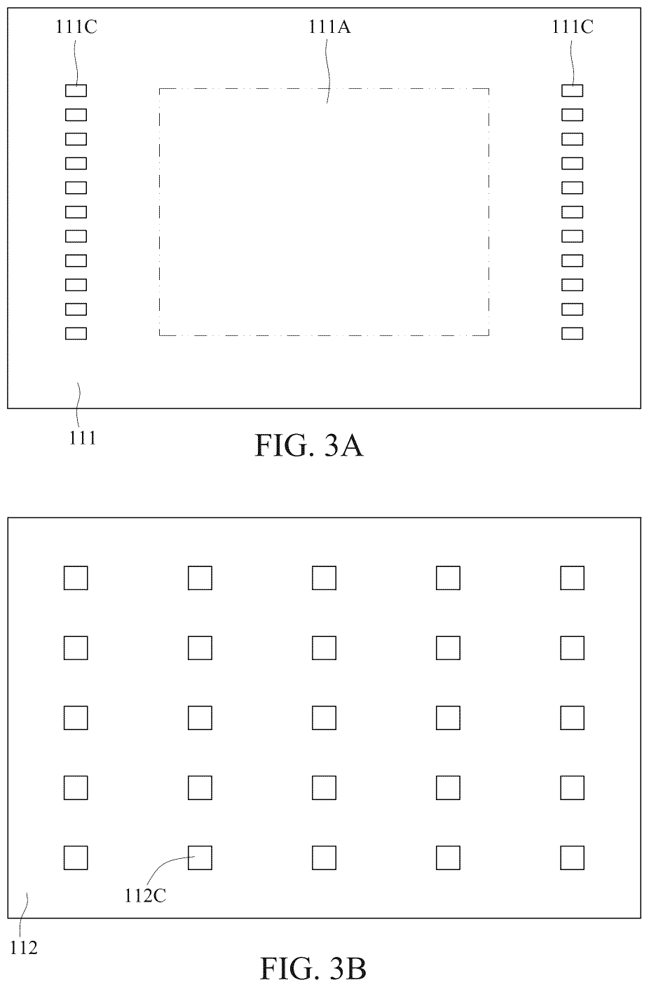

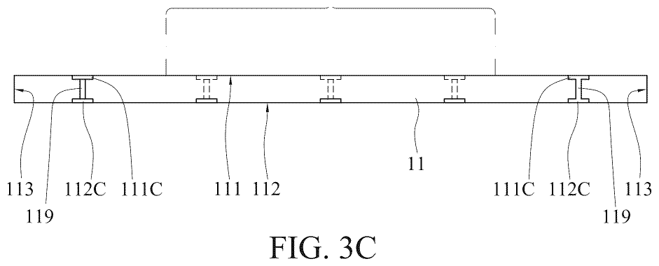

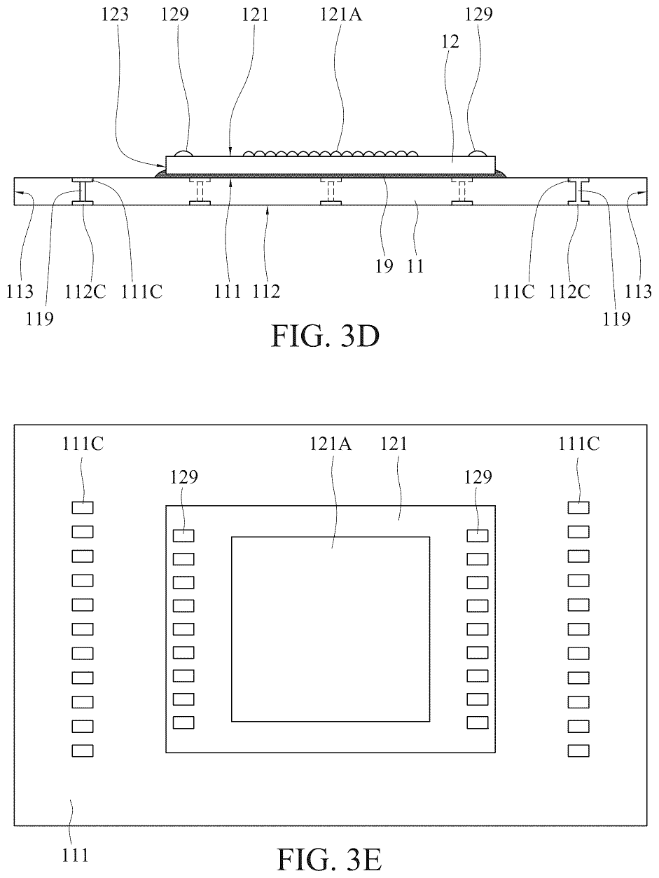

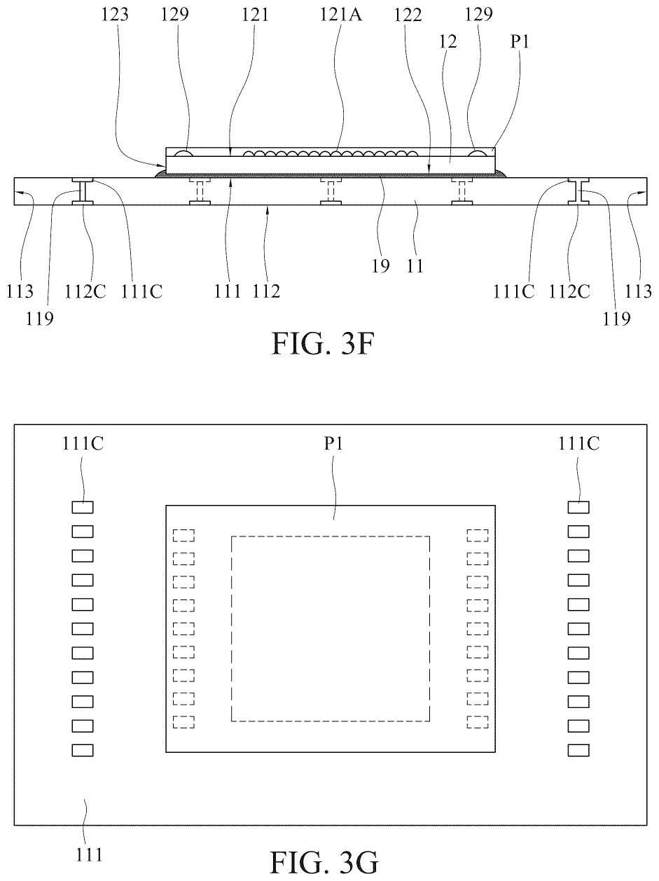

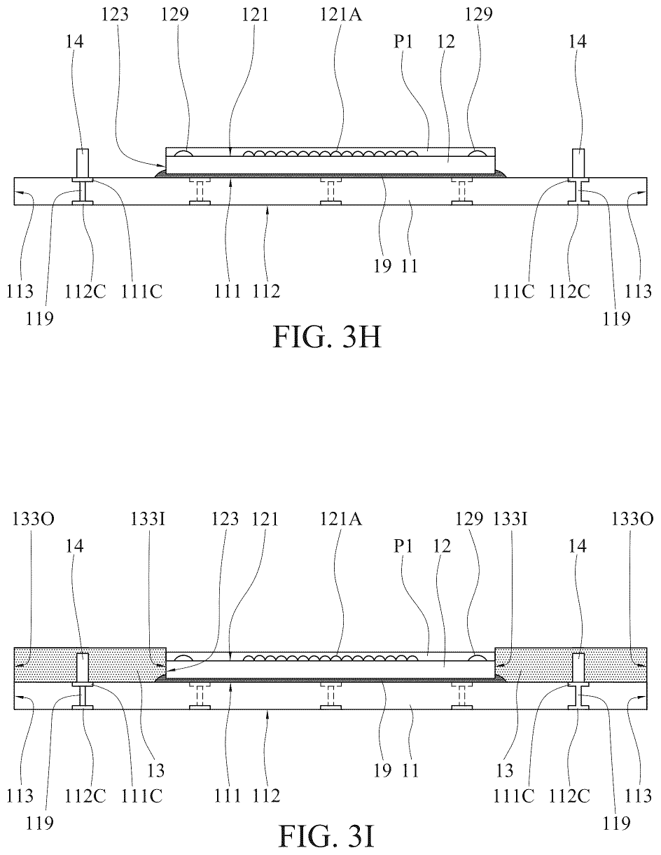

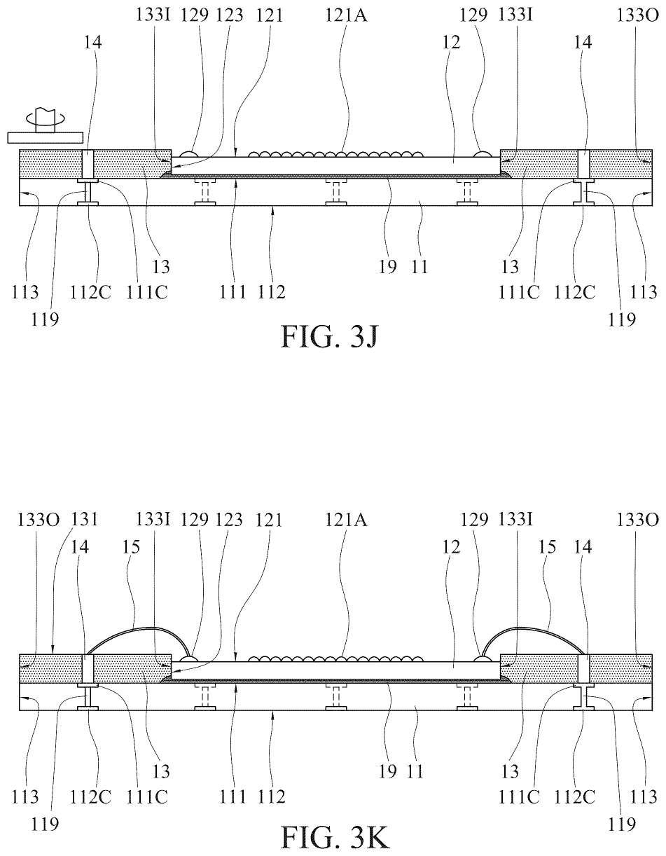

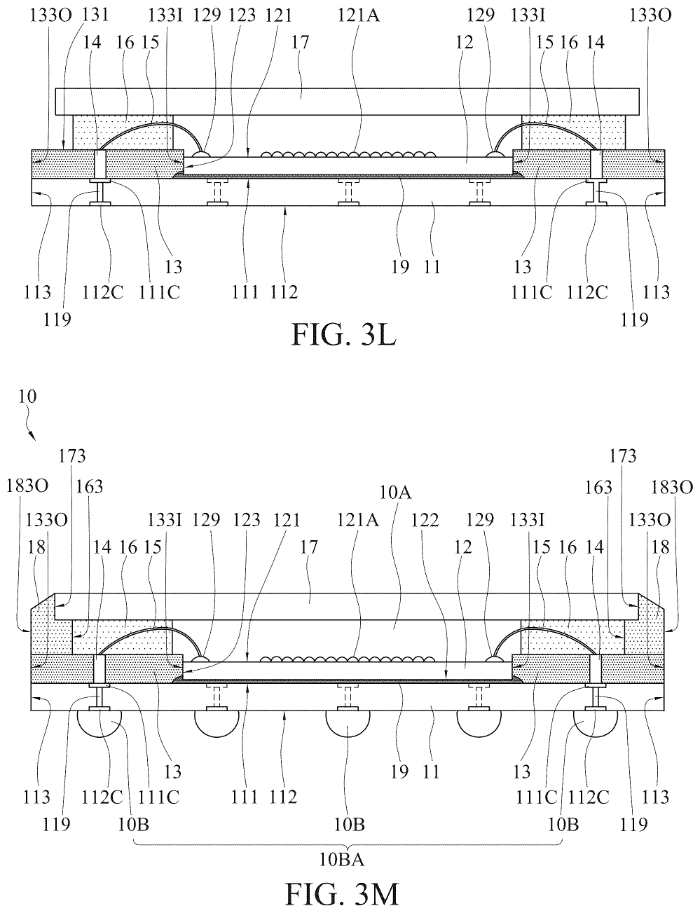

Referring further to FIG. 3A to FIG. 3C, which are respectively a schematic diagram of overlook view, a schematic diagram of upward view, and a schematic diagram of a section of a first substrate 11 according to an embodiment of the present disclosure. The first substrate 11 includes an upper surface 111, a lower surface 112, a side surface 113, and metal traces 119 formed between the upper surface 111 and the lower surface 112. The upper surface 111 of the first substrate 11 has a die-bonding area 111A and multiple upper contacts 111C disposed around the die-bonding area 111A. The upper contacts 111C shown in FIG. 3A are disposed on two opposite sides of the die-bonding area 111A, but the present disclosure is not limited to this, and the upper contacts 111C can also be disposed around the die-bonding area 111A to surround the die-bonding area 111A. The lower surface 112 of the first substrate 11 has multiple lower contacts 112C, solder balls 10B (shown in FIG. 2 and FIG. 3M) are further formed on the lower contacts 112C, these solder balls 10B form a ball grid array 10BA, and the upper contacts 111C are electrically connected to the ball grid array 10BA through the traces 119. In some embodiments, the first substrate 11 is a laminated material formed by multiple layers of glass fiber composite materials. In other embodiments, the first substrate 11 is a ceramic substrate made of materials such as silicon nitride (Si₃N₄), aluminum oxide (Al₂O₃), aluminum nitride (AlN), zirconium oxide (ZrO₂), zirconium oxide toughened alumina (ZTA), or beryllium oxide (BeO).

The image sensor chip 12 is fixed on the die-bonding area 111A of the upper surface 111 of the first substrate 11 by a die-bonding adhesive 19 in a mode that an active surface 121 faces upwards. The active surface 121 of the image sensor chip 12 includes an image sensing area 121A and multiple solder pads 129 disposed around the image sensing area 121A, and the image sensor chip 12 is electrically connected to an external circuit by the solder pads 129. In some embodiments, the solder pads 129 are disposed on two opposite sides of the image sensing area 121A.

The first molding layer 13 is disposed on the upper surface 111 of the first substrate 11 and covers a side surface 123 of the image sensor chip 12 to reduce the volume of an air chamber 10A in the chip packaging structure 10.

In some embodiments, an outer side surface 133O of the first molding layer 13 is flush with the side surface 113 of the first substrate 11. In addition, an inner side surface 133I of the first molding layer 13 is directly contacted with the side surface 123 of the image sensor chip 12, so the inner side surface 133I of the first molding layer 13 is also flush with the side surface 123 of the image sensor chip 12. In micro, an edge of the inner side surface 133I of the first molding layer 13 does not present a perfect right angle of 90°as shown in the figure, which depends on the die cavity design of a die used in the molding process and the shrinkage degree of a molding compound in the hardening process. However, even if the inner side surface 133I of the first molding layer 13 may have surface profile change caused by the above factors, it still accords the flush defined in the description.

The multiple conductive pillars 14 are disposed in the first molding layer 13 and respectively correspond to the multiple upper contacts 111C of the first substrate 11. In addition, a bottom end of each conductive pillar 14 is electrically connected to one of the upper contacts 111C of the first substrate 11, and a top end of each conductive pillar 14 is exposed on an upper surface 131 of the first molding layer 13. The conductive pillars 14 can be directly formed on the upper contacts 111C in a vertical wire bond mode and then are packaged by the first molding layer 13. In addition, the first molding layer 13 can also be formed firstly, then the positions where the conductive pillars 14 are to be formed are perforated, and finally metal materials are filled in the perforations through the manufacturing processes of electroplating, chemical vapor deposition or physical vapor deposition, so as to form the conductive pillars 14.

The metal wires 15 are formed in a wire bond mode, one end of each metal wire is bonded with one solder pad 129 of the image sensor chip 12, and the other end of each metal wire is bonded with the top end of one conductive pillar 14.

The second substrate 17 is fixed above the first substrate 11 through the adhesive layer 16 to seal the image sensor chip 12. The adhesive layer 16 is disposed on a top surface of the first molding layer 13 and surrounds the image sensor chip 12. In some embodiments, the adhesive layer 16 will cover the top ends of all conductive pillars 14. In other embodiments, the adhesive layer 16 further covers part of the metal wires 15, for example, 30% or more of the total length of the metal wires 15 is covered. In some embodiments, the second substrate 17 is made of glass, and has the light transmittance larger than 90% relative to visible light.

The second molding layer 18 is disposed on the upper surface 131 of the first molding layer 13 and covers a side surface 163 of the adhesive layer 16 and a side surface 173 of the second substrate 17. In some embodiments, the second molding layer 18 and the first molding layer 13 are made of the same materials, which are both molding compounds with epoxy resin as the main component.

As shown in FIG. 2, in some embodiments, the second molding layer 18 has an outer side surface 183O, and the outer side surface 183O of the second molding layer 18 is flush with the outer side surface 133O of the first molding layer 13. In addition, in some embodiments, a lower surface of the second molding layer 18 is flush with the upper surface 131 of the first molding layer 13.

As shown in FIG. 2, in some embodiments, an outer edge of the second substrate 17 is protruded from the adhesive layer 16, so that in the molding process of the second molding layer 18, the second molding layer 18 may also cover a part of a lower surface of the second substrate 17, such as a part of the lower surface adjacent to a peripheral edge of the second substrate 17.

In some embodiments, the die-bonding adhesive 19 is disposed between a back surface 122 of the image sensor chip 12 and the upper surface 111 of the first substrate 11, and also covers a part of the side surface 123 of the image sensor chip 12, particularly a part of the side surface 123 close to the back surface 122 of the image sensor chip 12. In some embodiments, the first molding layer 13 covers a peripheral edge of the die-bonding adhesive 19 and covers the side surface 123 of the image sensor chip 12, in which a part of the side surface 123 of the image sensor chip 12 is covered with the die-bonding adhesive 19, and the rest part is covered with the first molding layer 13.

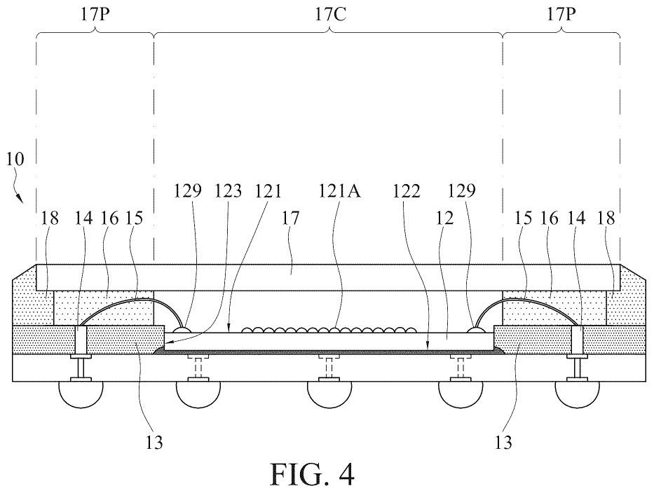

Referring to FIG. 4, in some embodiments, the second substrate 17 has a central area 17C and a peripheral area 17P surrounding the central area 17C. The central area 17C is defined as an area surrounded with an inner surface of the adhesive layer 16, and the peripheral area 17P is defined as an area outside the central area 17C. A geometric center of the central area 17C is substantially aligned with a geometric center of the image sensing area 121A of the image sensor chip 12, and at least a part of the peripheral area 17P is supported by the adhesive layer 16.

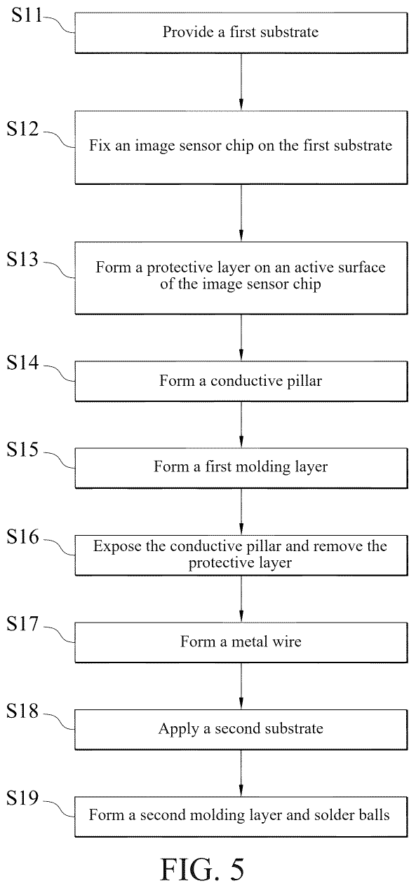

The formation of the chip packaging structure 10 is further described according to a flowchart of a manufacturing method of the chip packaging structure 10 in FIG. 5.

Step S11: The first substrate 11 is provided. As shown in FIG. 3A to FIG. 3C, the first substrate 11 includes the upper surface 111, the lower surface 112, the side surface 113, and the metal traces 119 formed between the upper surface 111 and the lower surface 112. The upper surface 111 of the first substrate 11 has a die-bonding area 111A and multiple upper contacts 111C disposed around the die-bonding area 111A. The lower surface 112 of the first substrate 11 has the multiple lower contacts 112C, and the upper contacts 111C are electrically connected to the lower contacts 112C through the traces 119.

Step S12: The image sensor chip 12 is fixed on the first substrate 11. As shown in FIG. 3D and FIG. 3E, the image sensor chip 12 is fixed on the die-bonding area 111A of the upper surface 111 of the first substrate 11 by the die-bonding adhesive 19 in a mode that the active surface 121 faces upwards. The active surface 121 of the image sensor chip 12 includes the image sensing area 121A and the multiple solder pads 129 disposed around the image sensing area 121A.

Step S13: A protective layer P1 is formed on the active surface 121 of the image sensor chip 12. As shown in FIG. 3F and FIG. 3G, the purpose of forming the protective layer P1 on the active surface 121 of the image sensor chip 12 to protect the active surface 121 of the image sensor chip 12 from being damaged by subsequent processes. The protective layer P1 can be made of polyimide (PI), but the present disclosure is not limited to this, and the protective layer can also be made of polybenzoxazole (PBO) or benzocyclobutene (BCB).

Step S14: The multiple conductive pillars 14 are formed. As shown in FIG. 3H, the multiple conductive pillars 14 are formed on each of the upper contacts 111C of the first substrate 11 in a vertical wire bond mode.

Step S15: The first molding layer 13 is formed. As shown in FIG. 3I, the conductive pillars 14 and the side surface 123 of the image sensor chip 12 are covered with the molding compound. The inner side surface 133I of the first molding layer 13 is directly contacted with the side surface 123 of the image sensor chip 12, so the inner side surface 133I of the first molding layer 13 is also flush with the side surface 123 of the image sensor chip 12.

Step S16: The conductive pillars 14 are exposed and the protective layer P1 is removed. As shown in FIG. 3J, the first molding layer 13 is thinned in a chemical mechanical polishing mode until the top ends of the conductive pillars 14 are exposed on the top surface of the first molding layer 13. Then the protective layer P1 on the active surface 121 of the image sensor chip 12 is removed with a chemical solution. When the protective layer P1 is made of polyimide (PI), the protective layer can be removed with an organic alkaline solution.

Step S17: The metal wires 15 are formed. As shown in FIG. 3K, the metal wires 15, such as gold wires, are used for electrically connecting the image sensor chip 12 to the first substrate 11 in a wire bond mode. One end of each metal wire 15 is bonded with one solder pad 129 of the image sensor chip 12, and the other end is bonded with the top end of one conductive pillar 14.

Step S18: The second substrate 17 is applied. As shown in FIG. 3L, the second substrate 17, such as a glass substrate, is fixed above the first substrate 11 by the adhesive layer 16 so as to seal the image sensor chip 12. The adhesive layer 16 is applied to the top surface of the first molding layer 13 and surrounds the image sensor chip 12, and simultaneously the adhesive layer 16 will cover the top ends of all the conductive pillars 14 and covers part of the metal wires 15.

Step S19: The second molding layer 18 and the solder balls 10B are formed. As shown in FIG. 3M, the side surface 163 of the adhesive layer 16, the side surface 173 of the second substrate 17 and the part of the lower surface of the second substrate 17 close to the outer peripheral edge are covered with the molding compound. Then, the solder balls 10B are formed on the lower contacts 112C of the first substrate 11, and the solder balls 10B form the ball grid array 10BA.

It is to be specifically noted that the above description and figures are both described by a single chip packaging structure 10, but actually, in the production of the chip packaging structure 10, each of the aforementioned steps is performed on multiple image sensor chips 12 at the same time. Therefore, after the aforementioned steps S11-S19 are implemented, an individual chip packaging structure 10 can be obtained by a cutting process. That is, a cutting surface of each chip packaging structure 10 defines the outer side surface 183O of the second molding layer 18, the outer side surface 133O of the first molding layer 13 and the side surface 113 of the first substrate 11, so that the outer side surface 183O, the outer side surface 133O and the side surface 113 are flush with each other.

One of the characteristics of the aforementioned chip packaging structure 10 is that the second substrate 17, the adhesive layer 16, the first molding layer 13 and the first substrate 11 jointly define the air chamber 10A, and the side surface 123 of the image sensor chip 12 is covered with the first molding layer 13 and is not exposed to the air chamber 10A. Therefore, compared with related technology, the air in the chip packaging structure 10 is relatively less, so that when the chip packaging structure 10 is subjected to other heat treatment processes (such as a reflow soldering process), the pressure difference between the air chamber 10A and the outside is not too large, the probability of failure of an adhesive surface between the second substrate 17 and the adhesive layer 16 or interface defects is reduced, and the overall yield and reliability of the chip packaging structure 10 are improved.

In the following description of the embodiments of the present disclosure, the terms “upper” or “lower” are used only for facilitating understanding of the relative relationship between the elements of each embodiment in conjunction with the accompanying drawings, and are not intended to limit the absolute positional relationship of the elements of the present disclosure in space.

What is claimed is:

1. A chip package structure, comprising
a first substrate comprising an upper surface, a lower surface, a side surface, and traces between the upper surface and the lower surface, wherein the upper surface has a die-bonding area and a plurality of upper contacts disposed around the die-bonding area, the lower surface has a ball grid array comprising a plurality of solder balls, and the plurality of upper contacts are electrically connected to the ball grid array through the traces;
an image sensor chip fixed on the die-bonding area on the upper surface of the first substrate, wherein an active surface of the image sensor chip comprises an image sensing area and a plurality of solder pads disposed around the image sensing area;
a first molding layer disposed on the upper surface of the first substrate and covering a side surface of the image sensor chip, wherein an outer side surface of the first molding layer is flush with the side surface of the first substrate, and an inner side surface of the first molding layer is flush with the side surface of the image sensor chip;
a plurality of conductive pillars disposed in the first molding layer, wherein a bottom end of each conductive pillar is electrically connected to one of the upper contacts, and a top end of each conductive pillar is exposed on an upper surface of the first molding layer;
a plurality of metal wires, one end of each metal wire being electrically connected to one solder pad of the image sensor chip, and the other end of each metal wire being electrically connected to the top end of one conductive pillar;
an adhesive layer disposed on the upper surface of the first molding layer, wherein the adhesive layer surrounds the image sensor chip, and an upper surface of the adhesive layer is higher than the active surface of the image sensor chip;
a second substrate fixed on the upper surface of the adhesive layer; and
a second molding layer disposed on the upper surface of the first molding layer and covering a side surface of the adhesive layer and a side surface of the second substrate.

2. The chip package structure according to claim 1, wherein the second molding layer has an outer side surface, and the outer side surface of the second molding layer is flush with the outer side surface of the first molding layer.

3. The chip package structure according to claim 2, wherein a lower surface of the second molding layer is flush with the upper surface of the first molding layer.

4. The chip package structure according to claim 3, wherein the second molding layer further covers a part of the lower surface of the second substrate.

5. The chip package structure according to claim 1, further comprising:
a die-bonding adhesive filled between the image sensor chip and the first substrate, wherein
the first molding layer covers a peripheral edge of the die-bonding adhesive and covers the side surface of the image sensor chip.

6. The chip package structure according to claim 5, wherein the die-bonding adhesive overs a part of the side surface of the image sensor chip, and the first molding layer covers the rest part of the side surface of the image sensor chip.

7. The chip package structure according to claim 1, wherein the adhesive layer covers the top ends of the plurality of conductive pillars.

8. The chip package structure according to claim 7, wherein the adhesive layer further covers a part of each metal wire.

9. The chip package structure according to claim 8, wherein the part of each metal wire covered with the adhesive layer is more than 30%.

10. The chip package structure according to claim 1, wherein the second substrate has a central area and a peripheral area surrounding the central area, the central area corresponds to the image sensor chip, and the peripheral area is supported by the upper surface of the adhesive layer.
